(19) United States
(12) Patent Application Publication
(10) Pub. No.: US 2025/0151336 A1
(43) Pub. Date: May 8, 2025

(54) THIN-FILM TRANSISTOR, DISPLAY DEVICE, AND METHOD OF FABRICATING THE THIN-FILM TRANSISTOR

(71) Applicant: Samsung Display Co., LTD., Yongin-si (KR)

(72) Inventors: Hiroshi OKUMURA, Yongin-si (KR); Dong Gyu JIN, Yongin-si (KR); Da Woon JUNG, Yongin-si (KR)

(21) Appl. No.: 18/752,965

(22) Filed: Jun. 25, 2024

(30) Foreign Application Priority Data
Nov. 7, 2023 (KR) 10-2023-0152532

(51) Int. Cl. H01L 29/786; H01L 29/66; H10K 59/121

(52) U.S. Cl. CPC H10D 30/6757; H10D 30/0321; H10K 59/1213

(57) ABSTRACT

Provided are a thin-film transistor, a display device including the thin-film transistor, and a method of fabricating the thin-film transistor. The thin-film transistor includes a semiconductor layer disposed on a substrate; and a gate electrode disposed on a gate insulating layer which covers the semiconductor layer, where the gate electrode overlaps a portion of the semiconductor layer. The semiconductor layer includes a channel portion overlapped by the gate electrode, a first electrode portion connected to an end of the channel portion and a second electrode portion connected to another end of the channel portion, a portion of the gate insulating layer between the channel portion and the gate electrode has a first thickness, and another portion of the gate insulating layer has a second thickness smaller than the first thickness.

This application claims priority to Korean Patent Application No. 10-2023-0152532, filed on Nov. 7, 2023, and all the benefits accruing therefrom under 35 U.S.C. § 119, the content of which in its entirety is herein incorporated by reference.

### BACKGROUND

### 1. Field

The present disclosure relates to a thin-film transistor, a display device including the thin-film transistor, and a method of fabricating the thin-film transistor.

### 2. Description of the Related Art

With the development of the information society, demand for display devices for displaying images of various forms is increasing. For example, display devices may be applied to various electronic devices such as, for example, smartphones, digital cameras, notebook computers, navigation devices, and smart televisions.

The display devices may be flat panel display devices such as, for example, liquid crystal display devices, field emission display devices, and light emitting display devices. Here, the light emitting display devices may include an organic light emitting display device including an organic light emitting element, an inorganic light emitting display device including an inorganic light emitting element such as, for example, an inorganic semiconductor, and a micro- or nano-light emitting display device including a micro- or nano-light emitting element.

An organic light emitting display device may display an image using light emitting elements, each including a light emitting layer of an organic light emitting material. The organic light emitting display device that displays an image using the self-light emitting elements may have relatively superior performance in terms of power consumption, response speed, luminous efficiency, luminance, and wide viewing angle, compared with other display devices.

A surface of a display device may include a display area where an image is displayed and a non-display area disposed around the display area. In the display area, emission areas that emit light with respective luminances and colors may be arranged.

### SUMMARY

The display device may include light emitting elements disposed in the emission areas and light-emitting pixel drivers electrically connected to the light emitting elements, respectively.

Each of the light-emitting pixel drivers may include two or more thin-film transistors.

When a thin-film transistor includes a semiconductor layer of polysilicon, secondary carriers due to impact ionization may accumulate in a channel. Accordingly, the electric potential of the channel may change, causing problems such as, for example, a threshold voltage shift (Vth shift) and a current kink effect.

In some aspects, if a surface of a portion of the semiconductor layer into which a dopant is injected includes excessive crystal defects due to the dopant injection process, a gate induced drain leakage (GIDL) current may increase due to the crystal defects.

Aspects of the present disclosure provide a thin-film transistor, a display device including the thin-film transistor, and a method of fabricating the thin-film transistor, in which secondary carriers due to impact ionization can be reduced, and a gate induced drain leakage (GIDL) current can be reduced.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a thin-film transistor comprises a semiconductor layer disposed on a substrate; and a gate electrode disposed on a gate insulating layer which covers the semiconductor layer and overlapping a portion of the semiconductor layer. The semiconductor layer comprises a channel portion overlapped by the gate electrode, a first electrode portion connected to an end of the channel portion and a second electrode portion connected to the other end of the channel portion. A portion of the gate insulating layer between the channel portion and the gate electrode has a first thickness. The other portion has a second thickness smaller than the first thickness.

The semiconductor layer further comprises sink portions disposed between each of the first electrode portion and the second electrode portion and the substrate, one of the sink portions contacts an end of the channel portion, and the other one contacts the other end of the channel portion.

The sink portions comprise a dopant of a first polarity type, the first electrode portion and the second electrode portion comprise a dopant of a second polarity type different from the first polarity type, and the doping concentration of the sink portions is lower than the doping concentration of the first electrode portion and the second electrode portion.

The second thickness is in the range of 100 to 1200 Å.

The first thickness is 1400 Å or more, and a difference between the first thickness and the second thickness is within the range of 200 to 1300 Å.

The thin-film transistor further comprises an interlayer insulating layer covering the gate insulating layer and the gate electrode.

The semiconductor layer further comprises sink auxiliary portions disposed between each of the first electrode portion and the second electrode portion and the channel portion and between each of the sink portions and the channel portion.

The sink auxiliary portions comprise the dopant of the second polarity type, and the doping concentration of the sink auxiliary portions is lower than the doping concentration of the first electrode portion and the second electrode portion.

According to an aspect of the present disclosure, there is provided a display device comprises a substrate comprising a display area in which emission areas are arranged; a circuit layer disposed on the substrate; and an element layer disposed on the circuit layer and comprising light emitting elements disposed in the emission areas, respectively. The circuit layer comprises light-emitting pixel drivers electrically connected to the light emitting elements, respectively, each of the light-emitting pixel drivers comprises two or more transistors. One of the two or more transistors comprises a semiconductor layer disposed on the substrate and a gate electrode disposed on a gate insulating layer which covers the semiconductor layer and overlapping a portion of the semiconductor layer, The semiconductor layer comprises a channel portion overlapped by the gate electrode, a first electrode portion connected to an end of the channel portion and a second electrode portion connected to the other end of the channel portion. A portion of the gate insulating layer between the channel portion and the gate electrode has a first thickness. The other portion has a second thickness smaller than the first thickness.

The semiconductor layer further comprises sink portions disposed between each of the first electrode portion and the second electrode portion and the substrate, one of the sink portions contacts an end of the channel portion, and the other one contacts the other end of the channel portion, the sink portions comprise a dopant of a first polarity type, the first electrode portion and the second electrode portion comprise a dopant of a second polarity type different from the first polarity type, and the doping concentration of the sink portions is lower than the doping concentration of the first electrode portion and the second electrode portion.

The circuit layer further comprises an interlayer insulating layer covering the gate insulating layer and the gate electrode.

The semiconductor layer further comprises sink auxiliary portions disposed between each of the first electrode portion and the second electrode portion and the channel portion and between each of the sink portions and the channel portion, the sink auxiliary portions comprise the dopant of the second polarity type, and the doping concentration of the sink auxiliary portions is lower than the doping concentration of the first electrode portion and the second electrode portion.

The second thickness is in the range of 100 to 1200 Å.

According to an aspect of the present disclosure, there is provided a method of fabricating a thin-film transistor, the method comprises placing a semiconductor layer on a substrate; placing a gate insulating layer having a first thickness to cover the semiconductor layer; placing a gate electrode on the gate insulating layer to overlap a portion of the semiconductor layer; placing the gate insulating layer excluding a portion overlapped by the gate electrode to a second thickness smaller than the first thickness; placing sink portions by injecting a dopant of a first polarity type into the semiconductor layer excluding the portion overlapped by the gate electrode; placing a channel portion, a first electrode portion and a second electrode portion by injecting a dopant of a second polarity type different from the first polarity type into the semiconductor layer excluding the portion overlapped by the gate electrode; and placing an interlayer insulating layer to cover the gate insulating layer and the gate electrode.

The placing of the gate electrode comprises placing a mask layer on a portion of a conductive layer stacked on the gate insulating layer and preparing the gate electrode by removing the conductive layer excluding the portion overlapped by the mask layer, and further comprising removing the mask layer after the placing of the gate insulating layer excluding the portion overlapped by the gate electrode to the second thickness smaller than the first thickness.

In the placing of the channel portion, the first electrode portion and the second electrode portion, the first electrode portion and the second electrode portion are placed on the sink portions, one of the sink portions and the first electrode portion contact an end of the channel portion, and the other one of the sink portions and the second electrode portion contact the other end of the channel portion.

The doping concentration of the sink portions is lower than the doping concentration of the first electrode portion and the second electrode portion.

The method further comprises, after the placing of the channel portion, the first electrode portion and the second electrode portion, reducing a width of the gate electrode; and placing sink auxiliary portions by injecting the dopant of the second polarity type into the semiconductor layer. The sink auxiliary portions are disposed between each of the first electrode portion and the second electrode portion and the channel portion and between each of the sink portions and the channel portion.

The doping concentration of the sink auxiliary portions is lower than the doping concentration of the first electrode portion and the second electrode portion.

In the placing of the gate insulating layer excluding the portion overlapped by the gate electrode to the second thickness smaller than the first thickness, the second thickness is in the range of 100 to 1200 Å.

A thin-film transistor according to embodiments includes a semiconductor layer disposed on a substrate and a gate electrode disposed on a gate insulating layer which covers the semiconductor layer. The semiconductor layer includes a channel portion overlapped by the gate electrode, a first electrode portion connected to an end of the channel portion, and a second electrode portion connected to the other end of the channel portion. In addition, a portion of the gate insulating layer between the channel portion and the gate electrode has a first thickness, and the other portion has a second thickness smaller than the first thickness.

According to embodiments, the semiconductor layer of the thin-film transistor may further include sink portions disposed between each of the first electrode portion and the second electrode portion and the substrate.

According to embodiments, the thin-film transistor may further include an interlayer insulating layer covering the gate insulating layer and the gate electrode.

According to embodiments, the first electrode portion and the second electrode portion of the semiconductor layer are covered with the gate insulating layer having the relatively thin second thickness.

Accordingly, hydrogen (H) introduced during a process of placing the interlayer insulating layer can easily reach surfaces of the first and second electrode portions of the semiconductor layer. That is, a relatively large amount of hydrogen (H) may flow to the surfaces of the first and second electrode portions of the semiconductor layer. Therefore, crystal defects included in the surfaces of the first and second electrode portions may be covered with a relatively large amount of hydrogen (H). As a result, a GIDL current due to the crystal defects on the surfaces of the first and second electrode portions can be reduced.

In some aspects, in a doping process for placing the first electrode portion and the second electrode portion and a doping process for placing the sink portions, a dopant may be injected into the semiconductor layer through the gate insulating layer having the second thickness which is relatively thin. Accordingly, an overspeed voltage for dopant injection can be lowered, and a depth to which a dopant is injected can be controlled relatively easily. Therefore, the reliability and uniformity of the characteristics of the thin-film transistor can be improved, and the fabrication cost of the thin-film transistor can be reduced.

Furthermore, since a difference in luminance between emission areas due to a difference between the characteristics of thin-film transistors can be reduced, the display quality of a display device including the thin-film transistors can be improved.

However, effects according to the embodiments of the present disclosure are not limited to the example embodiments described herein and various other effects are incorporated herein.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view of a display device according to embodiments;

FIG. 2 is a plan view of the display device of FIG. 1;

FIG. 3 is a cross-sectional view taken along line A-A′ of FIG. 2;

FIG. 4 is a plan view of part B of FIG. 2;

FIG. 5 is an equivalent circuit diagram of a light-emitting pixel driver in FIG. 4;

FIG. 6 is a cross-sectional view illustrating a first transistor, a sixth transistor, and a light emitting element of FIG. 5;

FIG. 7 is an enlarged view of part C of FIG. 6 according to an embodiment;

FIG. 8 is a flowchart illustrating a method of fabricating a thin-film transistor of FIG. 7;

FIGS. 9 through 14 are process diagrams illustrating operations in FIG. 8;

FIG. 15 is an enlarged view of part C of FIG. 6 according to an embodiment;

FIG. 16 is a flowchart illustrating a method of fabricating a thin-film transistor of FIG. 15; and

FIGS. 17 and 18 are process diagrams illustrating some of the operations in FIG. 16.

### DETAILED DESCRIPTION

Advantages and features of the present disclosure and methods of accomplishing the same may be understood more readily by reference to the following detailed description of example embodiments and the accompanying drawings. The present disclosure may, however, be embodied in many different forms and should not be construed as being limited to the embodiments set forth herein. Rather, the example embodiments are provided such that this disclosure will be thorough and complete and will fully convey the concept of the present disclosure to those skilled in the art, and the present disclosure will be defined by the appended claims.

It will be understood that when an element or layer is referred to as being “on” another element or layer, the element or layer can be directly on another element or layer or intervening elements or layers. Like reference numerals refer to like elements throughout the specification. Shapes, sizes, ratios, angles, numbers, etc. disclosed in the drawings for describing embodiments are merely an example, and the present disclosure is not limited to the illustrated details.

It will be understood that, although the terms first, second, third, etc., may be used herein to describe various elements, these elements should not be limited by these terms. These terms are only used to distinguish one element from another element. Thus, a first element discussed below could be termed a second element without departing from the teachings of the present disclosure.

The terms “about” or “approximately” as used herein are inclusive of the stated value and include a suitable range of deviation for the particular value as determined by one of ordinary skill in the art, considering the measurement in question and the error associated with measurement of the particular quantity. The term “about” can mean within one or more standard deviations, or within +30%, 20%, 10%, 5% of the stated value, for example.

The term “substantially,” as used herein, means approximately or actually. The term “substantially equal” means approximately or actually equal. The term “substantially the same” means approximately or actually the same.

Features of various embodiments of the present disclosure may be partially or entirely coupled to or combined with each other, and may be inter-operated and driven in technically various ways. The embodiments may be implemented independently from each other, or may be implemented together in a co-dependent relationship.

Hereinafter, specific embodiments will be described with reference to the accompanying drawings.

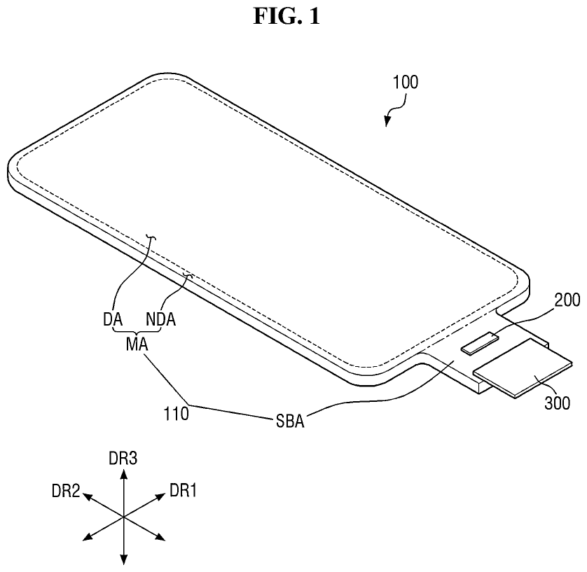

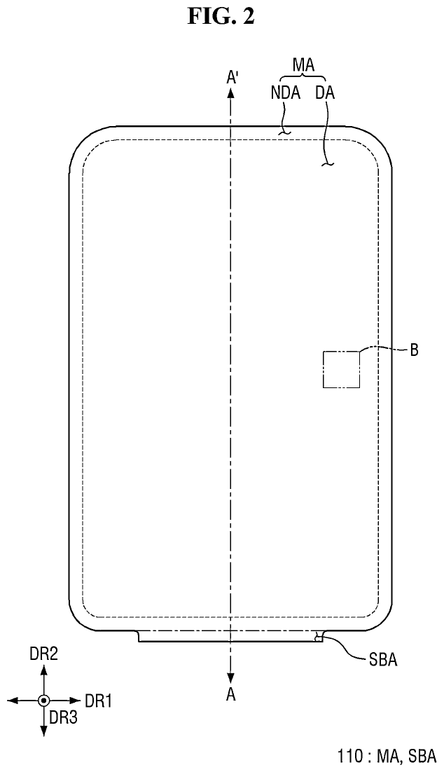

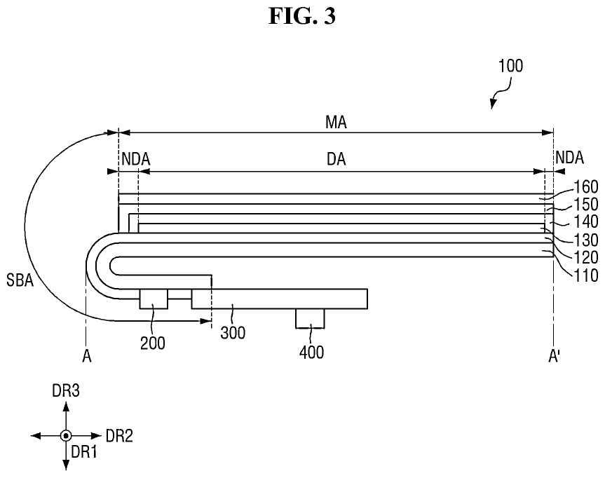

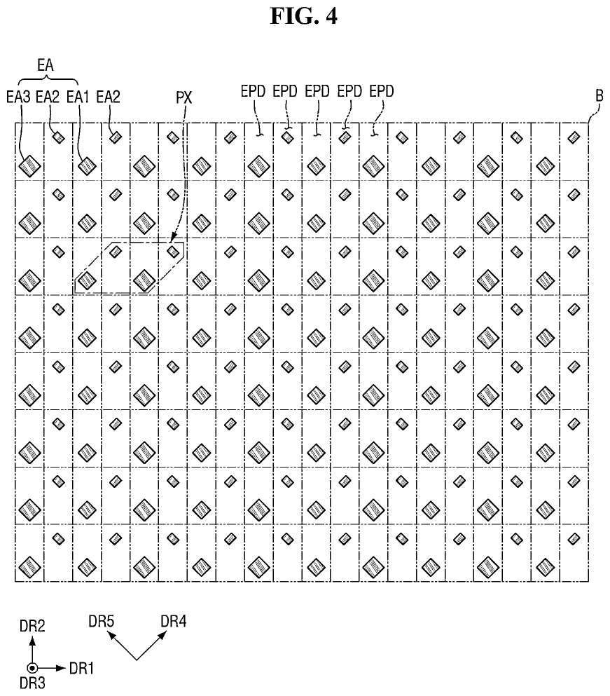

FIG. 1 is a perspective view of a display device 100 according to embodiments. FIG. 2 is a plan view of the display device 100 of FIG. 1. FIG. 3 is a cross-sectional view taken along line A-A′ of FIG. 2. FIG. 4 is a plan view of part B of FIG. 2.

Referring to FIGS. 1 and 2, the display device 100 is a device for displaying moving images or still images. The display device 100 may be used as a display screen in portable electronic devices such as, for example, mobile phones, smartphones, tablet personal computers (PCs), smart watches, watch phones, mobile communication terminals, electronic notebooks, electronic books, portable multimedia players (PMPs), navigation devices and ultra-mobile PCs (UMPCs), as well as in various products such as, for example, televisions, notebook computers, monitors, billboards, and Internet of things (IoT) devices.

The display device 10 may be a light emitting display device such as, for example, an organic light emitting display device using an organic light emitting diode, a quantum dot light emitting display device including a quantum dot light emitting layer, an inorganic light emitting display device including an inorganic semiconductor, or a micro- or nano-light emitting display device using a micro- or nano-light emitting diode. A case where the display device 100 is an organic light emitting display device will be mainly described herein. However, embodiments of the present disclosure are not limited thereto and is also applicable to display devices including an organic insulating material, an organic light emitting material, and a metal material.

The display device 100 may be formed flat, but embodiments of the present disclosure are not limited thereto. For example, the display device 100 may include curved portions formed at left and right ends and having a constant or varying curvature. In some aspects, the display device 100 may be formed to be flexible such that the display device 100 can be curved, bent, folded, or rolled.

As illustrated in FIGS. 1 through 3, the display device 100 includes a substrate 110.

The substrate 110 may include a main area MA corresponding to a display surface of the display device 100 and a sub-area SBA protruding from a side of the main area MA.

As illustrated in FIG. 2, the main area MA may include a display area DA located in most of the center and a non-display area NDA located around the display area DA.

The display area DA may be shaped like a rectangular plane having short sides in a first direction DR1 and long sides in a second direction DR2 crossing the first direction DR1. Each corner where a short side extending in the first direction DR1 meets a long side extending in the second direction DR2 may be rounded with a predetermined curvature or may be right-angled. The planar shape of the display area DA is not limited to a quadrilateral shape but may also be other polygonal shapes, a circular shape, or an oval shape.

The non-display area NDA may be disposed at edges of the main area MA to surround the display area DA.

The sub-area SBA may be an area protruding from the non-display area NDA of the main area MA to one side in the second direction DR2.

As a portion of the sub-area SBA is bent, the other portion of the sub-area SBA may be placed on a rear surface of the display device 100.

FIGS. 2 and 3 illustrate the display device 100 with a portion of the sub-area SBA bent.

Referring to FIG. 3, the display device 100 according to the embodiments includes the substrate 110, a circuit layer 120 disposed on the substrate 110, and an element layer 130 disposed on the circuit layer 120.

The display device 100 according to the embodiments may further include a sealing layer 140 disposed on the element layer 130 and a touch sensor layer 150 disposed on the sealing layer 140.

In some aspects, the display device 100 according to the embodiments may further include a polarization layer 160 disposed on the touch sensor layer 150 to reduce reflection of external light.

The substrate 110 may be formed of an insulating material such as, for example, polymer resin. For example, the substrate 110 may be formed of polyimide. The substrate 110 may be a flexible substrate that can be bent, folded, or rolled.

Alternatively, the substrate 110 may be formed of an insulating material such as, for example, glass.

The substrate 110 may include the main area MA and the sub-area SBA. The main area MA may include the display area DA and the non-display area NDA.

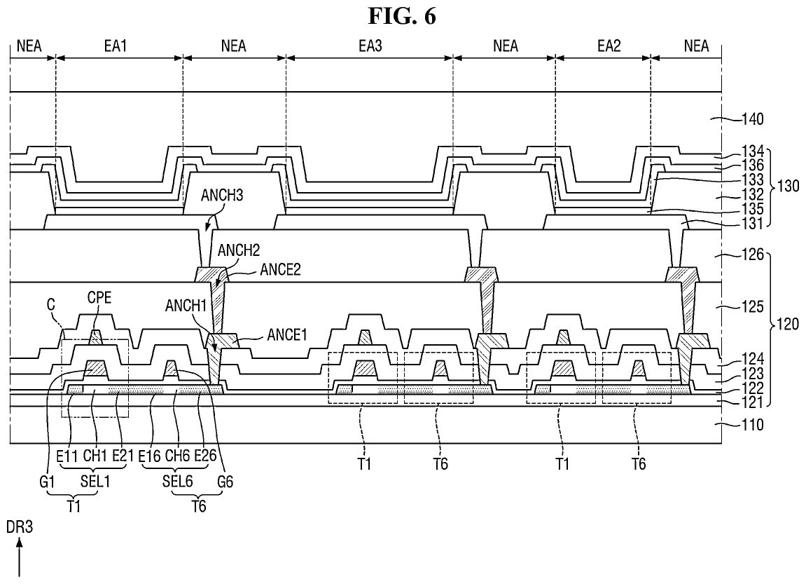

Referring to FIG. 4, the display area DA of the display device 100 according to the embodiments may include emission areas EA. In some aspects, the display area DA may further include a non-emission area NEA (see FIG. 6) between the emission areas EA.

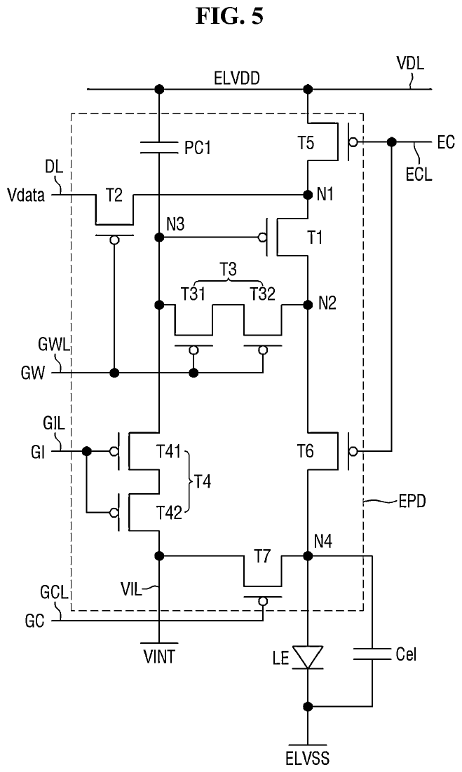

The element layer 130 may include light emitting elements LE (see FIG. 5) disposed in the emission areas EA, respectively.

The circuit layer 120 may include light-emitting pixel drivers EPD electrically connected to the light emitting elements LE of the element layer 130, respectively.

The light-emitting pixel drivers EPD may be arranged side by side in the first direction DR1 and the second direction DR2 in the display area DA.

The emission areas EA may have a rhombic planar shape or a rectangular planar shape. However, this is an example, and the planar shape of the emission areas EA according to an embodiment is not limited to that illustrated in and described with reference to FIG. 4. That is, the emission areas EA may also have a polygonal shape such as, for example, a quadrilateral, a pentagon, or a hexagon or may have a circular or oval planar shape including curved edges.

The emission areas EA may include first emission areas EA1 emitting light of a first color according to a predetermined wavelength band, second emission areas EA2 emitting light of a second color according to a wavelength band lower than that of the first color, and third emission areas EA3 emitting light of a third color according to wavelength band lower than that of the second color.

For example, the first color may be red according to a wavelength band of about 600 to 750 nm. The second color may be green according to a wavelength band of about 480 to 560 nm. The third color may be blue according to a wavelength band of about 370 to 460 nm.

The first emission areas EA1 and the third emission areas EA3 may be alternately arranged in at least one of the first direction DR1 and the second direction DR2.

The second emission areas EA2 may be arranged side by side with each other in at least one of the first direction DR1 and the second direction DR2.

In some aspects, the second emission areas EA2 may neighbor the first emission areas EA1 and the third emission areas EA3 in diagonal directions DR4 and DR5 crossing the first direction DR1 and the second direction DR2.

Among these emission areas EA, the first emission areas EA1, the second emission areas EA2, and the third emission areas EA3 adjacent to each other may form pixels PX which display respective luminances and colors.

In other words, each of the pixels PX may be a basic unit that displays various colors, including white, at a predetermined luminance level.

Each of the pixels PX may include at least one first emission area EA1, at least one second emission area EA2, and at least one third emission area EA3 adjacent to each other. Therefore, each of the pixels PX can display various colors through color mixing of light emitted from the first through third emission areas EA1 through EA3 adjacent to each other.

FIG. 5 is an equivalent circuit diagram of a light-emitting pixel driver EPD in FIG. 4.

Referring to FIG. 5, one of the light emitting elements LE of the element layer 130 may be electrically connected between one of the light-emitting pixel drivers EPD of the circuit layer 120 and a second power source ELVSS.

That is, an anode of the light emitting element LE may be electrically connected to the light-emitting pixel driver EPD, and the second power source ELVSS having a lower voltage level than a first power source ELVDD may be applied to a cathode of the light emitting element LE.

A capacitor Cel connected in parallel to the light emitting element LE is a parasitic capacitance between the anode and the cathode.

The circuit layer 120 may further include a first power line VDL which transmits the first power source ELVDD and an initialization power line VIL which transmits an initialization power source VINT.

The circuit layer 120 may further include a scan write line GWL which transmits a scan write signal GW, a scan initialization line GIL which transmits a scan initialization signal GI, an emission control line ECL which transmits an emission control signal EM, and a gate control line GCL which transmits a gate control signal GC.

A light-emitting pixel driver EPD (e.g., each light-emitting pixel driver EPD, two or more light-emitting pixel drivers EPDs) among the light-emitting pixel drivers EPD of the circuit layer 120 may include two or more thin-film transistors.

That is, the light-emitting pixel driver EPD may include a first transistor T1 which generates a driving current for driving the light emitting element LE, second through seventh transistors T2 through T7 which are electrically connected to the first transistor T1, and at least one pixel capacitor PC1.

The first transistor T1 is connected in series to the light emitting element LE between the first power source ELVDD and the second power source ELVSS.

That is, the first transistor T1 may be electrically connected between a first node N1 and a second node N2. The first node N1 is electrically connected to a first electrode (e.g., source electrode) of the first transistor T1. The second node N2 is electrically connected to a second electrode (e.g., drain electrode) of the first transistor T1.

In other words, the first electrode (e.g., source electrode) of the first transistor T1 may be electrically connected to the first power line VDL through the fifth transistor T5. In some aspects, the second electrode (e.g., drain electrode) of the first transistor T1 may be electrically connected to the anode of the light emitting element LE through the sixth transistor T6.

The pixel capacitor PC1 may be electrically connected between the first power line VDL and a third node N3. The third node N3 is electrically connected to a gate electrode of the first transistor T1.

That is, the gate electrode of the first transistor T1 may be electrically connected to the first power line VDL through the pixel capacitor PC1.

Accordingly, the electric potential of the gate electrode of the first transistor T1 may be maintained at a voltage charged in the first power line VDL.

The second transistor T2 may be electrically connected between a data line DL and the first node N1.

In other words, the second transistor T2 may be electrically connected between the first electrode of the first transistor T1 and the data line DL. The second transistor T2 may be turned on by the scan write signal GW of the scan write line GWL.

That is, the first electrode of the first transistor T1 may be electrically connected to the data line DL through the second transistor T2.

The fifth transistor T5 may be electrically connected between the first node N1 and the first power line VDL.

The sixth transistor T6 may be electrically connected between the second node N2 and a fourth node N4. The fourth node N4 is electrically connected to the anode of the light emitting element LE.

That is, the fifth transistor T5 may be electrically connected between the first electrode of the first transistor T1 and the first power line VDL.

The sixth transistor T6 may be electrically connected between the second electrode of the first transistor T1 and the anode of the light emitting element LE.

The fifth transistor T5 and the sixth transistor T6 may be turned on by the emission control signal EC of the emission control line ECL.

When a data signal Vdata of the data line DL is transmitted to the first electrode of the first transistor T1 through the turned-on second transistor T2, a voltage difference between the gate electrode of the first transistor T1 and the first electrode of the first transistor T1 may be a difference voltage between the first power source ELVDD and the data signal Vdata.

Here, when the voltage difference between the gate electrode of the first transistor T1 and the first electrode of the first transistor T1, that is, the gate-source voltage difference is equal to or greater than a threshold voltage, the first transistor T1 may be turned on. Accordingly, a drain-source current of the first transistor T1 which corresponds to the data signal Vdata may be generated.

Then, when the fifth transistor T5 and the sixth transistor T6 are turned on, the first transistor T1 may be connected in series to the light emitting element LE between the first power source ELVDD and the second power source ELVSS. Accordingly, the drain-source current of the first transistor T1 which corresponds to the data signal Vdata may be supplied as a driving current of the light emitting element LE.

Therefore, the light emitting element LE may emit light at a luminance level corresponding to the data signal Vdata.

The third transistor T3 may be electrically connected between the second node N2 and the third node N3. That is, the third transistor T3 may be electrically connected between the gate electrode of the first transistor T1 and the second electrode of the first transistor T1. The third transistor T3 may be turned on by the gate control signal GC of the gate control line GCL.

A voltage difference between the second node N2 and the third node N3 may be initialized through the turned-on third transistor T3.

The fourth transistor T4 may be electrically connected between an initialization voltage line VIL and the third node N3. That is, the fourth transistor T4 may be connected between the gate electrode of the first transistor T1 and the initialization voltage line VIL. The fourth transistor T4 may be turned on by the scan initialization signal GI of the scan initialization line GIL.

The electric potential of the third node N3 may be initialized through the turned-on fourth transistor T4.

The third transistor T3 and the fourth transistor T4 may be prepared as N-type MOSFETs.

The seventh transistor T7 may be electrically connected between the fourth node N4 and the initialization voltage line VIL. That is, the seventh transistor T7 may be electrically connected between the anode of the light emitting element LE and the initialization voltage line VIL. The seventh transistor T7 may be turned on by a gate control signal GC of a gate control line GCL.

The electric potential of the fourth node N4 may be initialized through the turned-on seventh transistor T7.

According to embodiments, the first through seventh transistors T1 through T7 may be prepared as P-type MOSFETs. However, this is an example, and at least some of the first through seventh transistors T1 through T7 may also be prepared as N-type MOSFETs. For example, the third transistor T3 and the fourth transistor T4 may be prepared as N-type MOSFETs, and the other transistors T1, T2 and T5 through T8 may be prepared as P-type MOSFETs.

Each of the light-emitting pixel drivers EPD of the circuit layer 120 may include two or more thin-film transistors T1 through T7, and each of the two or more thin-film transistors T1 through T7 may include a semiconductor layer and a gate electrode.

FIG. 6 is a cross-sectional view illustrating the first transistor T1, the sixth transistor T6, and the light emitting element LE of FIG. 5.

Referring to FIG. 6, the display device 100 according to the embodiments may include the substrate 110, the circuit layer 120 on the substrate 110, the element layer 130 on the circuit layer 120, and the sealing layer 140 on the element layer 130.

According to embodiments, the circuit layer 120 may include a semiconductor layer (including CH1, E11, E21, CH6, E16 and E26) disposed on the substrate 110, a gate insulating layer 122 covering the semiconductor layer, a first gate conductive layer (G1 and G6) disposed on the gate insulating layer 122, an interlayer insulating layer 123 covering the first gate conductive layer, a second gate conductive layer (CPE) disposed on the interlayer insulating layer 123, an additional interlayer insulating layer 124 covering the second gate conductive layer, a first source-drain conductive layer (ANCE1) disposed on the additional interlayer insulating layer 124, a first planarization layer 125 covering the first source-drain conductive layer, a second source-drain conductive layer (ANCE2) disposed on the first planarization layer 125, and a second planarization layer 126 covering the second source-drain conductive layer.

According to embodiments, the circuit layer 120 may further include a buffer layer 121 covering the substrate 110. In this case, the semiconductor layer (CH1, E11, E21, CH6, E16 and E26) may be disposed on the buffer layer 121.

The circuit layer 120 may include the light-emitting pixel drivers EPD which are respectively electrically connected to the light emitting elements LE disposed in the emission areas EA and lines which transmit various signals and voltages to the light-emitting pixel drivers EPD. Each of the light-emitting pixel drivers EPD may include the first transistor T1 and two or more transistors T2 through T7 electrically connected to the first transistor T1.

According to embodiments, the first transistor T1 may include a semiconductor layer SEL1 on the substrate 110 and a gate electrode G1 overlapping a portion CH1 of the semiconductor layer SEL1. The semiconductor layer SEL1 of the first transistor T1 may include a channel portion CH1 overlapped by the gate electrode G1, a first electrode portion E11 connected to an end of the channel portion CH1, and a second electrode portion E21 connected to the other end of the channel portion CH1.

Likewise, for example, the sixth transistor T6 may include a semiconductor layer SEL6 on the substrate 110 and a gate electrode G6 overlapping a portion CH6 of the semiconductor layer SEL6. The semiconductor layer SEL6 of the sixth transistor T6 may include a channel portion CH6 overlapped by the gate electrode G6, a first electrode portion E16 connected to an end of the channel portion CH6, and a second electrode portion E26 connected to the other end of the channel portion CH6.

The first electrode portion E16 of the sixth transistor T6 may be connected to the second electrode portion E21 of the first transistor T1.

The second electrode portion E26 of the sixth transistor T6 may be electrically connected to an anode 131 through a first anode connection electrode ANCE1 and a second anode connection electrode ANCE2.

According to embodiments, the second through fifth transistors T2 through T5 and the seventh transistor T7 have substantially the same structure as the first transistor T1 and the sixth transistor T6, and thus a redundant description thereof will be omitted.

The pixel capacitor PC1 may be prepared as an overlap area between the gate electrode G1 of the first transistor T1 and a pixel capacitor electrode CPE. The pixel capacitor electrode CPE may be disposed in the second gate conductive layer on the interlayer insulating layer 123.

The first anode connection electrode ANCE1 may be disposed in the first source-drain conductive layer on the additional interlayer insulating layer 124. The first anode connection electrode ANCE1 may be electrically connected to the second electrode portion E26 of the sixth transistor T6 through a first anode connection hole ANCH1 penetrating the additional interlayer insulating layer 124, the interlayer insulating layer 123, and the gate insulating layer 122.

The second anode connection electrode ANCE2 may be disposed in the second source-drain conductive layer on the first planarization layer 125. The second anode connection electrode ANCE2 may be electrically connected to the first anode connection electrode ANCE1 through a second anode connection hole ANCH2 penetrating the first planarization layer 125.

The anode 131 of the element layer 130 may be disposed on the second planarization layer 126 and may be electrically connected to the second anode connection electrode ANCE2 through a third anode connection hole ANCH3 penetrating the second planarization layer 126.

Accordingly, the anode 131 may be electrically connected to the second electrode portion E26 of the sixth transistor T6.

The element layer 130 may be disposed on the second planarization layer 126 of the circuit layer 120 and may include the light emitting elements LE respectively corresponding to the emission areas EA.

Each of the light emitting elements LE may include the anode 131 and a cathode 134 facing each other and a light emitting layer 133, in which the light emitting layer 133 is disposed between the anode 131 and the cathode 134.

That is, the element layer 130 may include the anodes 131 respectively corresponding to the emission areas EA, a pixel defining layer 132 corresponding to the non-emission area NEA and covering edges of the anodes 131, the light emitting layers 133 respectively disposed on the anodes 131, and the cathode 134 disposed on the light emitting layers 133 and the pixel defining layer 132.

Alternatively, each of the light emitting elements LE may further include a first common layer 135 disposed between the anode 131 and the light emitting layer 133 and a second common layer 136 disposed between the light emitting layer 133 and the cathode 134.

The anode 131 may be disposed in each of the emission areas EA and may be electrically connected to one of the light-emitting pixel drivers EPD of the circuit layer 120. The anode 131 may also be referred to as a pixel electrode.

The light emitting layers 133 may be formed of an organic light emitting material which converts electron-hole pairs into light.

The cathode 134 may be disposed in two or more neighboring emission areas EA of the display area DA and may be electrically connected to a line which transmits the second power source ELVSS. The cathode 134 may also be referred to as a common electrode.

The sealing layer 140 may be disposed on the circuit layer 120 and may cover the element layer 130.

For example, the sealing layer 140 may include a structure in which an organic layer formed of an organic insulating material is interposed between inorganic layers formed of an inorganic insulating material.

According to embodiments, a driving current corresponding to the data signal Vdata may be supplied to the light emitting element LE through two or more thin-film transistors T1 through T7 provided in each light-emitting pixel driver EPD of the circuit layer 120. In some cases, if a difference between luminance characteristics of the emission areas EA increases due to a difference between characteristics of the thin-film transistors T1 through T7, the difference may be seen as a spot defect. As a result, the display quality of the display device 100 may deteriorate.

Therefore, embodiments provide thin-film transistors in which a difference in characteristics can be reduced.

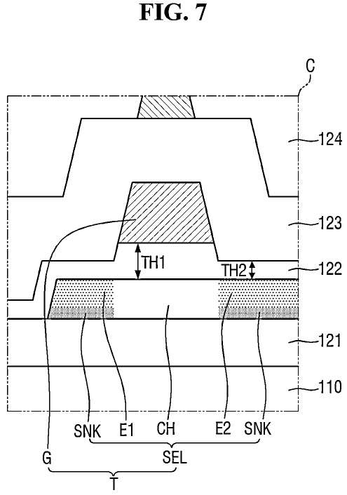

FIG. 7 is an enlarged view of part C of FIG. 6 according to an embodiment.

Referring to FIG. 7, a thin-film transistor T according to embodiments includes a semiconductor layer SEL disposed on the substrate 110 and a gate electrode G disposed on the gate insulating layer 122, which covers the semiconductor layer SEL, and overlapping a channel portion CH of the semiconductor layer SEL. The semiconductor layer SEL includes a channel portion CH overlapped by the gate electrode G, a first electrode portion E1 connected to an end of the channel portion CH, and a second electrode portion E2 connected to the other end of the channel portion CH.

According to embodiments, a portion of the gate insulating layer 122 between the channel portion CH and the gate electrode G has a first thickness TH1, and another portion of the gate insulating layer 122 has a second thickness TH2 smaller than the first thickness TH1.

According to embodiments, the gate insulating layer 122 and the gate electrode G may be covered with the interlayer insulating layer 123.

For example, the interlayer insulating layer 123 may include silicon nitride (SiNₓ). In this case, some of the hydrogen (H) introduced during a process of stacking the interlayer insulating layer 123 may pass through the gate insulating layer 122 and reach a surface of the semiconductor layer SEL, and the hydrogen (H) may cover crystal defects of the surface of the semiconductor layer SEL.

According to embodiments, the first electrode portion E1 and the second electrode portion E2 of the semiconductor layer SEL are covered with the gate insulating layer 122 having a relatively thin second thickness TH2.

In this case, the second thickness TH2 supports, during the process of placing the interlayer insulating layer 123, an increase in the amount of hydrogen (H) that passes through the gate insulating layer 122 and reaches a surface of each of the first electrode portion E1 and the second electrode portion E2. Accordingly, crystal defects on the surface of each of the first electrode portion E1 and the second electrode portion E2 may be decreased, thus reducing a gate induced drain leakage (GIDL) current caused by the crystal defects. Therefore, the characteristics of the thin-film transistor T can be improved.

In some aspects, the semiconductor layer SEL of the thin-film transistor T according to the embodiments may further include sink portions SNK disposed between the first and second electrode portions E1 and E2 and the substrate 110, respectively.

That is, the first electrode portion E1 and the second electrode portion E2 may be disposed on the sink portions SNK.

One of the sink portions SNK may contact an end of the channel portion CH together with the first electrode portion E1.

Likewise, another of the sink portions SNK may contact the other end of the channel portion CH together with the second electrode portion E2.

The sink portions SNK may include a dopant of a first polarity type.

The first electrode portion E1 and the second electrode portion E2 may include a dopant of a second polarity type different from the first polarity type.

That is, the first and second electrode portions E1 and E2 and the sink portions SNK may have opposite polarity types.

In an example in which the thin-film transistor T is a P-type MOSFET, the first electrode portion E1 and the second electrode portion E2 may include a P-type dopant, and the sink portions SNK may include an N-type dopant.

In another example, in which the thin-film transistor T is an N-type MOSFET, the first electrode portion E1 and the second electrode portion E2 may include an N-type dopant, and the sink portions SNK may include a P-type dopant.

The P-type dopant may be at least one of trivalent elements such as, for example, boron (B), aluminum (Al), indium (In), and gallium (Ga).

The N-type dopant may be at least one of pentavalent elements such as, for example, phosphorus (P), antimony (Sb), and arsenic (As).

In some embodiments, the doping concentration of the sink portions SNK may be lower than the doping concentration of the first electrode portion E1 and the second electrode portion E2, which may reduce leakage current caused by the sink portions SNK. That is, embodiments of the present disclosure may include preparing the sink portions SNK as lightly doped regions.

In an example in which the thin-film transistor T is prepared as a P-type MOSFET, the first electrode portion E1 and the second electrode portion E2 may be p⁺ semiconductor regions, and the sink portions SNK may be n-semiconductor regions.

One of the first electrode portion E1 and the second electrode portion E2 may be a source of the thin-film transistor T, and the other of the first electrode portion E1 and the second electrode portion E2 may be a drain of the thin-film transistor T.

As described herein, the thin-film transistor T according to the embodiments may include sink portions SNK of a polarity type different from that of the first electrode portion E1 and the second electrode portion E2. Accordingly, secondary carriers accumulated in the channel CH due to impact ionization can be discharged through at least one of the sink portions SNK. Therefore, since the potential variation of the channel CH due to accumulation of carriers can be prevented, the characteristics of the thin-film transistor T can be improved.

According to embodiments, in a doping process for placing the sink portions SNK and a doping process for placing the first electrode portion E1 and the second electrode portion E2, a dopant may reach the semiconductor layer SEL through the gate insulating layer 122 having a relatively thin second thickness TH2.

Accordingly, for example, the second thickness TH2 supports increasing the dose of the dopant, which, in turn, may reduce the process time of the doping processes.

According to embodiments, since the semiconductor layer SEL is entirely covered by the gate insulating layer 122, the semiconductor layer SEL does not include a portion exposed to an etching process. Therefore, damage to the surface of the semiconductor layer SEL by an etching material can be prevented.

In some aspects, since doping processes are performed on the semiconductor layer SEL covered with the gate insulating layer 122 having the second thickness TH2, a depth to which a dopant is injected can be adjusted more easily. Therefore, the process of preparing the sink portions SNK adjacent to the substrate 110 and the process of preparing the first electrode portion E1 and the second electrode portion E2 on the sink portions SNK can be performed more easily, and the boundary between the first and second electrode portions E1 and E2 and the sink portions SNK can be clearer.

According to embodiments, the first thickness TH1 may be 1400 Å or more.

According to embodiments, the second thickness TH2 may be in the range of 200 to 1300 Å.

In an example in which the second thickness TH2 is less than 200 Å, the surface of the semiconductor layer SEL excluding a portion overlapped by the gate electrode G may not be sufficiently protected by the gate insulating layer 122. Therefore, the surface of the semiconductor layer SEL may be relatively directly exposed to etching and doping processes on the gate insulating layer 122 and thus may be greatly damaged.

In some other examples, when the second thickness TH2 exceeds 1300 Å, hydrogen (H) cannot easily pass through the gate insulating layer 122. Therefore, the amount of hydrogen (H) that reaches the surface of the semiconductor layer SEL excluding the portion overlapped by the gate electrode G may be less than a critical amount required to cover crystal defects. As a result, the effect of covering the crystal defects included in the surface of the semiconductor layer SEL may not be induced.

For example, in a simulation of a first comparative example in which the sink portions SNK are not included and the gate insulating layer 122 has a uniform thickness of 1400 Å, the GIDL current for a gate voltage Vg of 11-14 V was 0.57 pA.

In addition, in a simulation of a second comparative example in which the sink portions SNK are included and the gate insulating layer 122 has a uniform thickness of 1400 Å, the GIDL current for a gate voltage Vg of 11-14 V was 0.67 pA.

In contrast, for example, in a simulation of an embodiment which includes the gate insulating layer 122 having a first thickness TH1 of 1400 Å and a second thickness TH2 of 800 Å and the sink portions SNK, the GIDL current for a gate voltage Vg of 11-14 V was 0.42 pA. As is apparent from the above results, a thin-film transistor T according to the embodiments may have improved GIDL current characteristics compared with the first and second comparative examples.

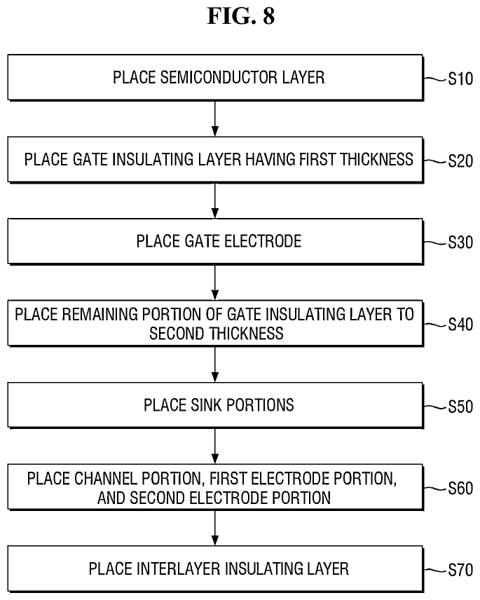

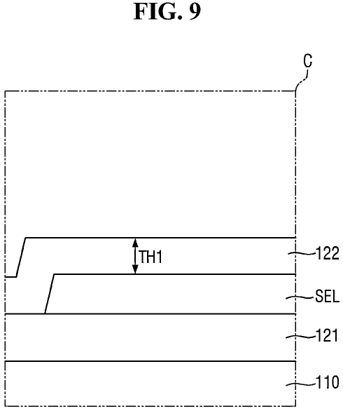

FIG. 8 is a flowchart illustrating a method of fabricating the thin-film transistor T of FIG. 7. FIGS. 9 through 14 are process diagrams illustrating operations in FIG. 8.

It is to be understood that descriptions herein of “placing” an element (e.g., a semiconductor layer SEL, a gate insulating layer 122, a gate electrode G, and the like) as described herein may include features and processes supported by aspects of the present disclosure for “forming,” “depositing,” “modifying,” or the like with reference to the element on or adjacent another element in association with fabricating a thin-film transistor T.

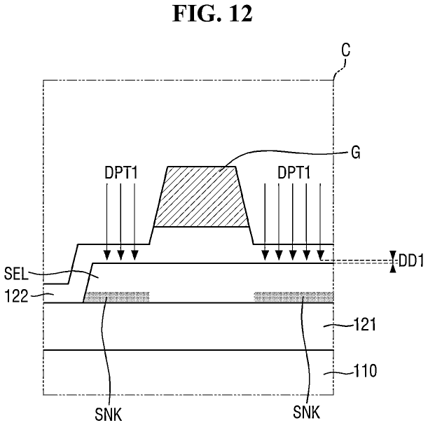

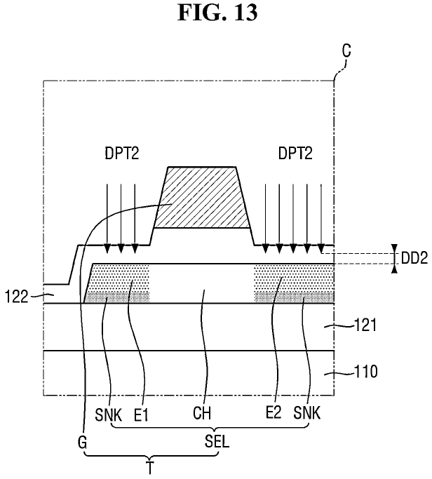

Referring to FIG. 8, a method of fabricating a thin-film transistor T according to embodiments includes placing a semiconductor layer SEL on a substrate 110 (operation S10), placing a gate insulating layer 122 having a first thickness TH1 to cover the semiconductor layer SEL (operation S20), placing a gate electrode G on the gate insulating layer 122 to overlap a portion of the semiconductor layer SEL (operation S30), placing the gate insulating layer 122 excluding a portion overlapped by the gate electrode G to a second thickness TH2 smaller than the first thickness TH1 (operation S40), placing sink portions SNK by injecting a dopant DPT1 (see FIG. 12) of a first polarity type into the semiconductor layer SEL excluding the portion overlapped by the gate electrode G (operation S50), placing a channel portion CH, a first electrode portion E1 and a second electrode portion E2 by injecting a dopant DPT2 (see FIG. 13) of a second polarity type different from the first polarity type into the semiconductor layer SEL excluding the portion overlapped by the gate electrode G (operation S60), and placing an interlayer insulating layer 123 to cover the gate insulating layer 122 and the gate electrode G (operation S70).

Expressed another way, the method of fabricating a thin-film transistor T according to embodiments may include forming a semiconductor layer SEL on a substrate 110 (operation S10). The method may include forming a gate insulating layer 112 according to a first thickness TH1, wherein the gate insulating layer 112 covers the semiconductor layer SEL (operation S20). The method may include forming a gate electrode G on the gate insulating layer 112, wherein the gate electrode G overlaps a portion of the semiconductor layer SEL and a portion of the gate insulating layer 112 (operation S30). The method may include etching a second portion of the gate insulating layer 112 which is not overlapped by the gate electrode G, to a second thickness smaller than the first thickness (operation S40). The method may include forming sink portions SNK by injecting a dopant DPT1 of a first polarity type into the semiconductor layer SEL, excluding a portion of the semiconductor layer SEL overlapped by the gate electrode G (operation S50). The method may include forming a channel portion CH, a first electrode portion E1, and a second electrode portion E2 by injecting a dopant DPT2 of a second polarity type different from the first polarity type into the semiconductor layer SEL, excluding the portion of the semiconductor layer SEL overlapped by the gate electrode G (operation S60). The method may include forming an interlayer insulating layer 123 which covers the gate insulating layer 122 and the gate electrode G (operation S70).

Referring to FIG. 9, after a buffer layer 121 is formed to cover the substrate 110, the method may include partially removing a semiconductor material layer stacked on the buffer layer 121 and forming the semiconductor layer SEL (operation S10).

The buffer layer 121 may include an inorganic insulating material.

The semiconductor layer SEL may include a polysilicon material or an amorphous silicon material.

Next, the method may include forming the gate insulating layer 122 having the first thickness TH1 and covering the semiconductor layer SEL (operation S20). The gate insulating layer 122 may be formed of an inorganic insulating material stacked on the buffer layer 121.

The first thickness TH1 may be about 1400 Å or more.

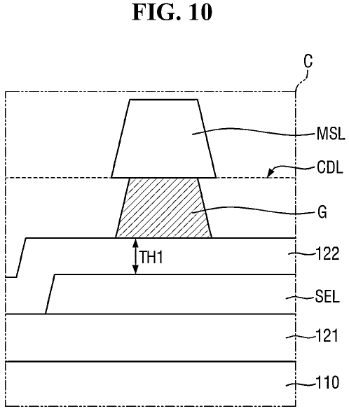

Referring to FIG. 10, the forming of the gate electrode G (operation S30) may include forming a mask layer MSL on a portion of a conductive layer CDL stacked on the gate insulating layer 122 and preparing the gate electrode G by removing the conductive layer CDL excluding the portion overlapped by the mask layer MSL.

That is, the method may include maintaining a portion of the conductive layer CDL which is overlapped by the mask layer MSL, and the portion may form the gate electrode G.

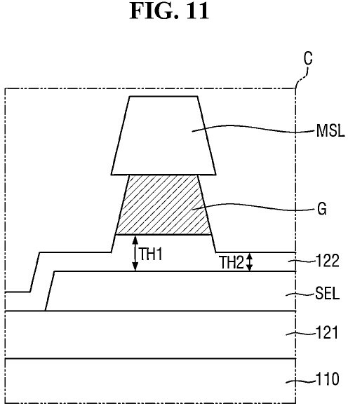

Referring to FIG. 11, the method may include etching the gate insulating layer 122 while the mask layer MSL is left unremoved. Accordingly, the gate insulating layer 122 excluding the portion overlapped by the gate electrode G may have the second thickness TH2 smaller than the first thickness TH1 (operation S40).

In an example in which the first thickness TH1 is about 1400 Å or more, the method may include performing the etching process on the gate insulating layer 122 until the thickness of the gate insulating layer 122 is reduced by a thickness of about 200 to about 1300 Å.

That is, a difference between the first thickness TH1 and the second thickness TH2 may be within the range of about 200 to about 1300 Å.

For example, the second thickness TH2 may be within the range of about 100 to about 1200 Å.

In this case, in doping and stacking processes to be described later, the second thickness TH2 of the gate insulating layer 122 may maintain the protection effect and facilitate the transmission of hydrogen (H) for covering crystal defects and doping depth control.

Referring to FIG. 12, after the mask layer MSL is removed, the method may include performing a doping process of injecting the dopant DPT1 of the first polarity type. Accordingly, the sink portions SNK including the dopant of the first polarity type may be formed in a lower part of the semiconductor layer SEL excluding the portion overlapped by the gate electrode G (operation S50).

In an example in which the first thickness TH1 of the gate insulating layer 122 is 1400 Å, a first doping process for forming the sink portions SNK may be implemented according to a peak position DD1 of a doping depth to which the dopant DPT1 of the first polarity type is injected into the semiconductor layer SEL. The peak position DD1 may be spaced apart from a surface of the semiconductor layer SEL by about 20 Å in a direction DR3 in which the semiconductor layer SEL and the gate insulating layer 122 are stacked.

Referring to FIG. 13, the method may include performing a doping process of injecting the dopant DPT2 of the second polarity type different from the first polarity type. Accordingly, the method may include forming the first electrode portion E1 and the second electrode portion E2 including the dopant of the second polarity type in an upper part of the semiconductor layer SEL, excluding the portion overlapped by the gate electrode G (operation S60).

Here, since the portion of the semiconductor layer SEL which is overlapped by the gate electrode G is excluded from the two doping processes (operations S50 and S60), the overlapped portion is prepared as the channel portion CH which maintains semiconductor characteristics.

In an example in which the first thickness TH1 of the gate insulating layer 122 is 1400 Å, a second doping process for forming the first electrode portion E1 and the second electrode portion E2 may be implemented according to a peak position DD2 of a doping depth to which the dopant DPT2 of the second polarity type is injected into the semiconductor layer SEL. The peak position DD2 may be spaced apart from the surface of the semiconductor layer SEL by about 85 Å in the direction DR3 in which the semiconductor layer SEL and the gate insulating layer 122 are stacked.

The first electrode portion E1 and the second electrode portion E2 may become a source electrode and a drain electrode by having conductivity. For example, the dose of dopant ions per unit area may be about 5E13 cm⁻² or more during the second doping process for placing the first electrode portion E1 and the second electrode portion E2.

Here, surfaces of the first electrode portion E1 and the second electrode portion E2 exposed to the two doping processes may include a relatively large number of crystal defects. In some cases, the crystal defects on the surface of the semiconductor layer SEL can cause a GIDL current. As described herein, embodiments of the present disclosure support techniques which may prevent or mitigate the crystal defects.

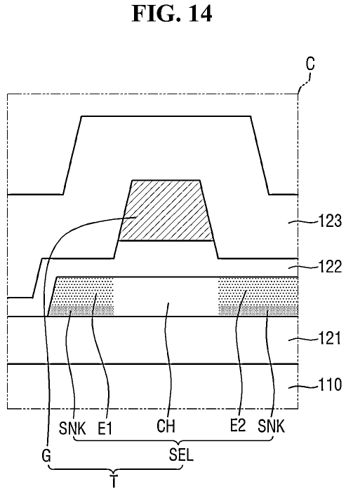

For example, as illustrated in FIG. 14, the method may include forming the interlayer insulating layer 123 on the gate insulating layer 122, in which the interlayer insulating layer 123 covers the gate electrode G. The interlayer insulating layer 123 may be formed of an inorganic insulating material stacked on the gate insulating layer 122.

The interlayer insulating layer 123 may include silicon nitride (SiNₓ).

Here, some of the hydrogen (H) introduced during the process of stacking silicon nitride (SiNₓ) may pass through the gate insulating layer 122 having the second thickness TH2 and reach the surfaces of the first electrode portion E1 and the second electrode portion E2. Accordingly, for example, the introduced hydrogen (H) may cover crystal defects included in the surfaces of the first electrode portion E1 and the second electrode portion E2, thus lowering the GIDL current.

Therefore, embodiments of the present disclosure provide a thin-film transistor T having improved characteristics (e.g., a reduced number of crystal defects).

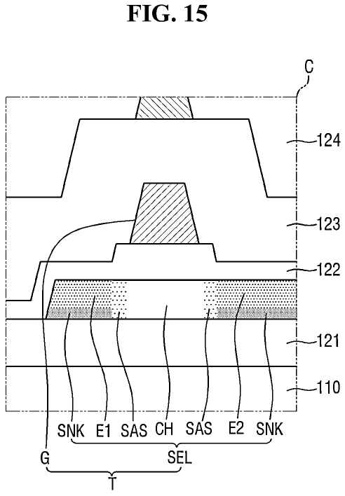

FIG. 15 is an enlarged view of part C of FIG. 6 according to an embodiment.

The thin-film transistor T described with reference to FIG. 15 includes aspects of the thin-film transistor T described with reference to FIG. 7 as described herein, and repeated descriptions of like elements are omitted for brevity. Referring to FIG. 15, the thin-film transistor T according to an embodiment is substantially the same as the embodiments illustrated in FIG. 7 except that a semiconductor layer SEL further includes sink auxiliary portions SAS disposed between each of first and second electrode portions E1 and E2 and a channel portion CH and between each of sink portions SNK and the channel portion CH. For example, a first sink auxiliary portion SAS (e.g., left side in FIG. 15) may be disposed between the first electrode portion E1 and the channel portion CH, and the first sink auxiliary portion may be disposed between a first sink portion SNK (e.g., left side in FIG. 15) and the channel portion CH. A second sink auxiliary portion SAS (e.g., right side in FIG. 15) may be disposed between the second electrode portion E2 and the channel portion CH, and the second sink auxiliary portion SAS may be disposed between the second sink portion SNK (e.g., right side in FIG. 15) and the channel portion CH. Therefore, any redundant description will be omitted below.

According to an embodiment, the sink auxiliary portions SAS may include a dopant of a second polarity type, for example, the second polarity type associated with the first electrode portion E1 and the second electrode portion E2.

To reduce leakage current due to the sink auxiliary portions SAS, the doping concentration of the sink auxiliary portions SAS may be lower than the doping concentration of the first electrode portion E1 and the second electrode portion E2. That is, the method may include preparing the sink auxiliary portions SAS as lightly doped regions. In an example in which the thin-film transistor T is prepared as a P-type MOSFET, the first electrode portion E1 and the second electrode portion E2 may be p⁺ semiconductor regions, the sink portions SNK may be n-semiconductor regions, and the sink auxiliary portions SAS may be p⁻ semiconductor regions.

As described herein, according to an embodiment, since the sink auxiliary portions SAS are disposed between the channel portion CH and the sink portions SNK, a potential difference between the channel portion CH and the sink portions SNK may be lowered. Accordingly, secondary carriers accumulated in the channel CH can be discharged more easily, thus further improving the characteristics of the thin-film transistor T.

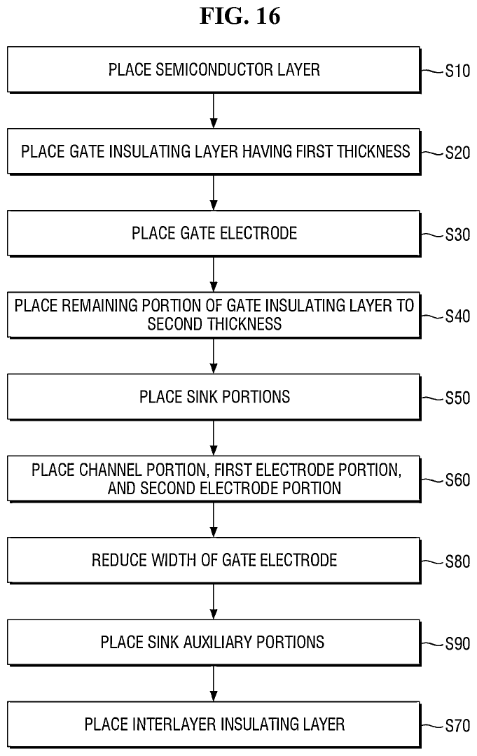

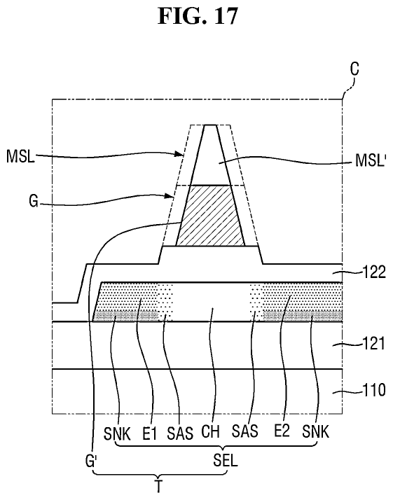

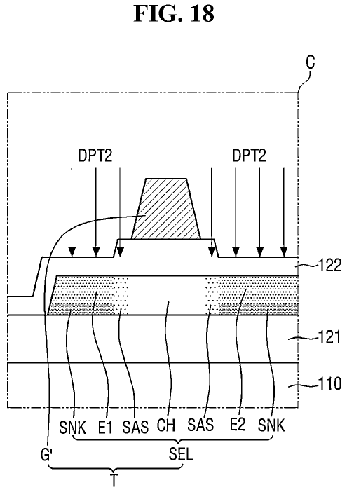

FIG. 16 is a flowchart illustrating a method of fabricating the thin-film transistor T of FIG. 15. FIGS. 17 and 18 are process diagrams illustrating some of the operations in FIG. 16.

The method described with reference to FIG. 16 may include aspects of the method described with reference to FIGS. 8 through 14, and repeated descriptions of like elements are omitted for brevity. Referring to FIG. 16, the method of fabricating a thin-film transistor T according to an embodiment is substantially the same as the embodiments illustrated in FIGS. 8 through 14 except that the method may further include reducing a width of a gate electrode G (e.g., resulting in a gate electrode G′ of a reduced width compared to gate electrode G) (operation S80) and forming sink auxiliary portions SAS by injecting a dopant of a second polarity type into a semiconductor layer SEL (operation S90) after forming a channel portion CH, a first electrode portion E1, and a second electrode portion E2 (operation S60). Therefore, any redundant description will be omitted below.

Referring to FIG. 17, after the placing of the channel portion CH, the first electrode portion E1, and the second electrode portion E2 (operation S60), the method may include performing an etching process on a mask layer MSL to produce a mask layer MSL′ with a reduced width. Then, the method may include performing another etching process on a gate electrode G to produce the gate electrode G′ with a reduced width (operation S80).

Here, the reduced width of the gate electrode G′ may be smaller than a width of a gate insulating layer 122 having a first thickness TH1 and a width of the channel portion CH.

Referring to FIG. 18, the method may include forming the sink auxiliary portions SAS including the dopant DPT2 of a second polarity type in the channel portion CH of the semiconductor layer SEL, excluding a portion of the channel portion CH which is overlapped by the gate electrode G′ with the reduced width (operation S90). For example, the method may include performing a doping process of injecting a dopant DPT2 of the second polarity type in association with forming the sink auxiliary portions SAS.

Here, since the sink auxiliary portions SAS include the dopant DPT2 of the second polarity type like the first electrode portion E1 and the second electrode portion E2, the characteristics of the first electrode portion E1 and the second electrode portion E2 may be unchanged by the third doping process described herein with reference to forming the sink auxiliary portions SAS.

In the third doping process for placing the sink auxiliary portions SAS, the dopant DPT2 of the second polarity type may pass through the gate insulating layer 122 having the first thickness TH1 to reach the semiconductor layer SEL.

Accordingly, the method may include support a process having relatively low complexity for preparing lightly doped sink auxiliary portions SAS.

In the descriptions of the methods and processes herein, the operations may be performed in a different order than the order shown and/or described, or the operations may be performed in different orders or at different times. Certain operations may also be left out of the methods and processes, one or more operations may be repeated, or other operations may be added. Descriptions that an element “may be disposed,” “may be formed,” and the like include methods, processes, and techniques for disposing, forming, positioning, and modifying the element, and the like in accordance with example aspects described herein.

The effects of the present disclosure are not restricted to the effects set forth herein. The above and other effects of the present disclosure will become more apparent to one of daily skill in the art to which the present disclosure pertains by referencing the claims.

What is claimed is:

1. A thin-film transistor comprising:
a semiconductor layer disposed on a substrate; and
a gate electrode disposed on a gate insulating layer which covers the semiconductor layer, wherein the gate electrode overlaps a portion of the semiconductor layer,
wherein:
the semiconductor layer comprises a channel portion overlapped by the gate electrode, a first electrode portion connected to an end of the channel portion, and a second electrode portion connected to another end of the channel portion,
a portion of the gate insulating layer between the channel portion and the gate electrode has a first thickness, and
another portion of the gate insulating layer has a second thickness smaller than the first thickness.

2. The thin-film transistor of claim 1, wherein:
the semiconductor layer further comprises a first sink portion disposed between the first electrode portion and the substrate and a second sink portion disposed between the second electrode portion and the substrate,
one of the first sink portion and the second sink portion contacts an end of the channel portion, and
another of the first sink portion and the second sink portion contacts another end of the channel portion.

3. The thin-film transistor of claim 2, wherein:
the first sink portion and the second sink portion comprise a dopant of a first polarity type,
the first electrode portion and the second electrode portion comprise a dopant of a second polarity type different from the first polarity type, and
a doping concentration of the first sink portion and the second sink portion is lower than a doping concentration of the first electrode portion and the second electrode portion.

4. The thin-film transistor of claim 1, wherein the second thickness ranges from 100 Å to 1200 Å.

5. The thin-film transistor of claim 1, wherein the first thickness is 1400 Å or more, and a difference between the first thickness and the second thickness ranges from 200 Å to 1300 Å.

6. The thin-film transistor of claim 1, further comprising an interlayer insulating layer covering the gate insulating layer and the gate electrode.

7. The thin-film transistor of claim 3, wherein the semiconductor layer further comprises:
a first sink auxiliary portion disposed between the first electrode portion and the channel portion, wherein the first sink auxiliary portion is further disposed between the first sink portion and the channel portion; and
a second sink auxiliary portion disposed between the second electrode portion and the channel portion, wherein the second sink auxiliary portion is further disposed between the second sink portion and the channel portion.

8. The thin-film transistor of claim 7, wherein the first sink auxiliary portion and the second sink auxiliary portion comprise the dopant of the second polarity type, and a doping concentration of the first sink auxiliary portion and the second sink auxiliary portion is lower than the doping concentration of the first electrode portion and the second electrode portion.

9. A display device comprising:
a substrate comprising a display area in which emission areas are arranged;
a circuit layer disposed on the substrate; and
an element layer disposed on the circuit layer and comprising light emitting elements respectively disposed in the emission areas,
wherein:
the circuit layer comprises light-emitting pixel drivers electrically connected to the light emitting elements, respectively, each of the light-emitting pixel drivers comprising two or more transistors,
wherein at least one of the two or more transistors comprises:
a semiconductor layer disposed on the substrate; and
a gate electrode disposed on a gate insulating layer which covers the semiconductor layer, wherein the gate electrode overlaps a portion of the semiconductor layer,
wherein:
the semiconductor layer comprises a channel portion overlapped by the gate electrode, a first electrode portion connected to an end of the channel portion and a second electrode portion connected to another end of the channel portion,
a portion of the gate insulating layer between the channel portion and the gate electrode has a first thickness, and
another portion of the gate insulating layer has a second thickness smaller than the first thickness.

10. The display device of claim 9, wherein:
the semiconductor layer further comprises a first sink portion disposed between the first electrode portion and the substrate and a second sink portion disposed between the second electrode portion and the substrate,
one of the first sink portion and the second sink portion contacts an end of the channel portion,
another of the first sink portion and the second sink portion contacts another end of the channel portion,
the first sink portion and the second sink portion comprise a dopant of a first polarity type,
the first electrode portion and the second electrode portion comprise a dopant of a second polarity type different from the first polarity type, and
a doping concentration of the first sink portion and the second sink portion is lower than a doping concentration of the first electrode portion and the second electrode portion.

11. The display device of claim 9, wherein the circuit layer further comprises an interlayer insulating layer covering the gate insulating layer and the gate electrode.

12. The display device of claim 10, wherein the semiconductor layer further comprises:
a first sink auxiliary portion disposed between the first electrode portion and the channel portion, wherein the first sink auxiliary portion is further disposed between the first sink portion and the channel portion; and
a second sink auxiliary portion disposed between the second electrode portion and the channel portion, wherein the second sink auxiliary portion is further disposed between the second sink portion and the channel portion,
wherein the first sink auxiliary portion and the second sink auxiliary portion comprise the dopant of the second polarity type, and a doping concentration of the first sink auxiliary portion and the second sink auxiliary portion is lower than the doping concentration of the first electrode portion and the second electrode portion.

13. The display device of claim 9, wherein the second thickness ranges from 100 to 1200 Å.

14. A method of fabricating a thin-film transistor, the method comprising:
forming a semiconductor layer on a substrate;
forming a gate insulating layer according to a first thickness, wherein the gate insulating layer covers the semiconductor layer;
forming a gate electrode on the gate insulating layer, wherein the gate electrode overlaps a portion of the semiconductor layer and a portion of the gate insulating layer;
etching a second portion of the gate insulating layer which is not overlapped by the gate electrode, to a second thickness smaller than the first thickness;
forming sink portions by injecting a dopant of a first polarity type into the semiconductor layer, excluding a portion of the semiconductor layer overlapped by the gate electrode;
forming a channel portion, a first electrode portion, and a second electrode portion by injecting a dopant of a second polarity type different from the first polarity type into the semiconductor layer, excluding the portion of the semiconductor layer overlapped by the gate electrode; and
forming an interlayer insulating layer which covers the gate insulating layer and the gate electrode.

15. The method of claim 14, wherein the forming of the gate electrode comprises:
placing a mask layer on a portion of a conductive layer stacked on the gate insulating layer; and
forming the gate electrode by removing the conductive layer, excluding a portion of the conductive layer overlapped by the mask layer, and
the method further comprises removing the mask layer after the etching of the second portion of the gate insulating layer which is not overlapped by the gate electrode to the second thickness smaller than the first thickness.

16. The method of claim 14, wherein the forming of the channel portion, the first electrode portion, and the second electrode portion comprises:
forming the first electrode portion and the second electrode portion on the sink portions, wherein the first electrode portion and a first sink portion of the sink portions contact an end of the channel portion, and the second electrode portion and a second sink portion of the sink portions contact another end of the channel portion.

17. The method of claim 16, wherein a doping concentration of the sink portions is lower than a doping concentration of the first electrode portion and the second electrode portion.

18. The method of claim 16, further comprising, after the forming of the channel portion, the first electrode portion, and the second electrode portion,
reducing a width of the gate electrode; and
forming sink auxiliary portions by injecting the dopant of the second polarity type into the semiconductor layer,
wherein the sink auxiliary portions comprise:
a first sink auxiliary portion disposed between the first electrode portion and the channel portion, wherein the first sink auxiliary portion is further disposed between the first sink portion and the channel portion; and
a second sink auxiliary portion disposed between the second electrode portion and the channel portion, wherein the second sink auxiliary portion is further disposed between the second sink portion and the channel portion.

19. The method of claim 18, wherein a doping concentration of the sink auxiliary portions is lower than a doping concentration of the first electrode portion and the second electrode portion.

20. The method of claim 14, wherein in the etching of the second portion of the gate insulating layer which is not overlapped by the gate electrode to the second thickness smaller than the first thickness, the second thickness ranges from 100 Å to 1200 Å.
